(19) United States
(12) Patent Application Publication
(10) Pub. No.: US 2004/0188610 A1
(43) Pub. Date: Sep. 30, 2004

(54) Crystal analyzing apparatus capable of three-dimensional crystal analysis

(75) Inventor: Yukinori Hirose, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 10/686,652

(22) Filed: Oct. 17, 2003

(30) Foreign Application Priority Data
Mar. 27, 2003 (JP) 2003-087417

(51) Int. Cl. H01J 37/256; G01N 23/20

(52) U.S. Cl. 250/310; 250/306

(57) ABSTRACT

A crystal analyzing apparatus is provided which is capable of performing three-dimensional crystal analysis. With an electron beam (B2) scanning a measured surface (S1), a detecting unit (6) detects an electron backscatter diffraction pattern from each pixel in the measured surface (S1) and a data processing block (9) analyzes the data (D1) to obtain two-dimensional distribution data (K1) about the crystal orientation of the measured surface (S1). Next, an ion beam (B1) is emitted to slice the sample (11), so as to form the next measured section (S2) at a position inward from the measured surface (S1) by a given distance (L). Two-dimensional distribution data (K2) about the crystal orientation of the measured surface (S2) is then obtained. These operation steps are repeated to sequentially obtain crystal-orientation two-dimensional distribution data (K3) to (Kn) about measured surfaces (S3) to (Sn). Next, the data processing block (9) stacks the two-dimensional distribution data (K1) to (Kn) in this order to construct crystal-orientation three-dimensional distribution data (Q).

### BACKGROUND OF THE INVENTION

1. Field of the Invention

The present invention relates to a crystal analyzing apparatus.

2. Description of the Background Art

Conventional crystal analyzing apparatuses illuminate the surface of a sample with an electron beam, detect electron backscatter diffraction patterns (EBSPs) produced from the sample surface as a result of the electron beam illumination, and measure the crystal orientation of the sample on the basis of the results of the detection (for example, refer to Japanese Patent Application Laid-Open No. 2002-5857).

Since crystals are formed of three-dimensionally overlapping grains, three-dimensional crystal analysis is desired. However, conventional crystal analyzing apparatuses are only capable of two-dimensional crystal analysis of sample surfaces.

### SUMMARY OF THE INVENTION

An object of the invention is to provide a crystal analyzing apparatus capable of performing three-dimensional crystal analysis.

According to a first aspect of the invention, a crystal analyzing apparatus includes an ion beam emitting portion, an electron beam emitting portion, a detecting portion, a data processing portion, and an analyzing portion. The ion beam emitting portion emits an ion beam onto a sample to sequentially form a plurality of sections of the sample. The electron beam emitting portion emits an electron beam to each of the plurality of sections. The detecting portion detects, with respect to each of the plurality of sections, an electron backscatter diffraction pattern produced from the sample as a result of the electron beam emission. The data processing portion constructs three-dimensional data about a crystal orientation distribution of the sample on the basis of the results detected by the detecting portion. The analyzing portion defines an arbitrary section in the three-dimensional data and performs a crystal analysis about the arbitrary section.

It it thus possible to perform three-dimensional crystal analysis.

According to a second aspect of the invention, a crystal analyzing apparatus includes an ion beam emitting portion, an electron beam emitting portion, a detecting portion, a data processing portion, and an analyzing portion. The ion beam emitting portion emits an ion beam onto a sample to sequentially form a plurality of sections of the sample. The electron beam emitting portion emits an electron beam to each of the plurality of sections. The detecting portion detects, with respect to each of the plurality of sections, an electron backscatter diffraction pattern produced from the sample as a result of the electron beam emission. The data processing portion constructs three-dimensional data about a crystal orientation distribution of the sample on the basis of the results detected by the detecting portion. The analyzing portion extracts an arbitrary three-dimensional region from the three-dimensional data and performs a crystal analysis about the arbitrary three-dimensional region.

It is thus possible to perform three-dimensional crystal analysis.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram showing the configuration of a crystal analyzing apparatus according to a first preferred embodiment of the invention;

FIG. 2 is a block diagram showing the configuration of a crystal analyzing apparatus according to a modification of the first preferred embodiment;

FIG. 3 is a side view of the sample;

FIG. 4 is a schematic diagram showing an example of three-dimensional distribution data;

FIG. 5 is a schematic diagram showing an example of an arbitrary section defined in the three-dimensional data;

FIG. 6 is a plan view of the section;

FIG. 7 is a diagram showing an example of an inverse pole figure generated about the section;

FIG. 8 is a schematic diagram showing an example of a grain distribution image generated about the section;

FIG. 9 is a graph representing a relation between the grain size and the number of grains;

FIG. 10 is a schematic diagram showing an example of a grain boundary characteristic image generated about the section;

FIG. 11 is a schematic diagram showing an example of a Σ-value distribution image generated about the section;

FIG. 12 is a schematic diagram showing an example of a phase distribution image generated about the section;

FIG. 13 is a schematic diagram showing an example of a region arbitrarily extracted from three-dimensional data;

FIG. 14 is a schematic diagram showing an example of a grain distribution image generated about the region;

FIG. 15 is a schematic diagram showing an example of a grain boundary characteristic image generated about the region;

FIG. 16 is a schematic diagram showing an example of a Σ-value distribution image generated about the region; and

FIG. 17 is a schematic diagram showing an example of a phase distribution image generated about the region.

### DESCRIPTION OF THE PREFERRED EMBODIMENTS

First Preferred Embodiment

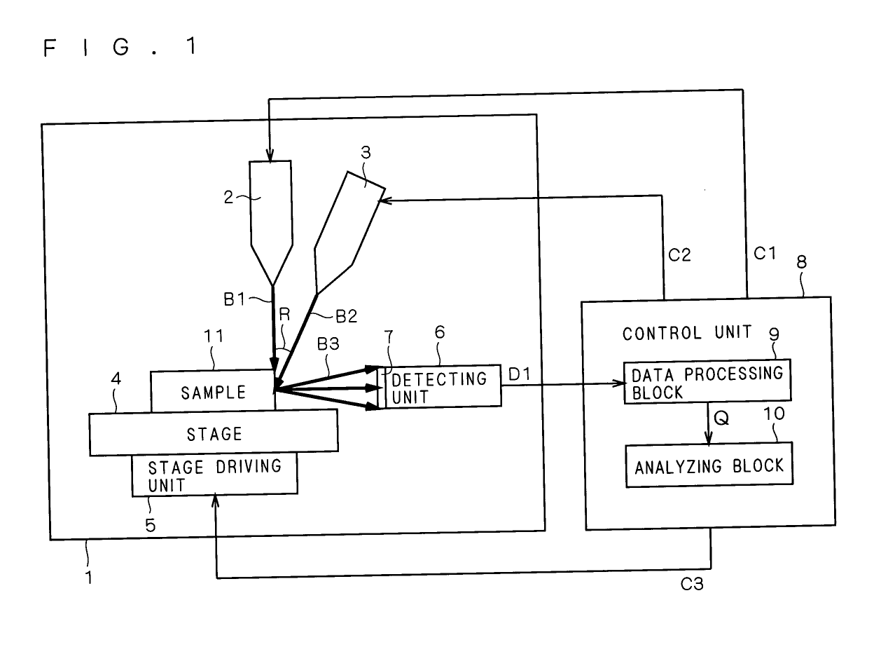

FIG. 1 is a block diagram showing the configuration of a crystal analyzing apparatus according to a first preferred embodiment of the invention. A vacuum chamber 1 contains: an ion beam emitting device 2, e.g. an FIB (Focused Ion Beam) system; an electron beam emitting device 3, e.g. a SEM (Scanning Electron Microscope) system; a stage 4 on which a crystalline sample 11 is mounted; a stage driving unit 5 for driving the stage 4; and a detecting unit 6 for detecting electron backscatter diffraction patterns. A screen 7 is positioned in front of the detecting unit 6. The optical axis of the ion beam emitting device 2 is perpendicular to the ground and to the top surfaces of the sample 11, stage 4, and stage driving unit 5. The optical axis of the electron beam emitting device 3 is inclined at an angle R of approximately 20 to 30° with respect to the optical axis of the ion beam emitting device 2.

A control unit 8, e.g. a computer, is provided outside of the vacuum chamber 1 to control the ion beam emitting device 2, electron beam emitting device 3, and stage driving unit 5. The control unit 8 includes a data processing block 9 connected to an output of the detecting unit 6 and an analyzing block 10 connected to an output of the data processing block 9. The ion beam emitting device 2, electron beam emitting device 3 and stage driving unit 5 are controlled respectively by control signals C1 to C3 supplied from the control unit 8.

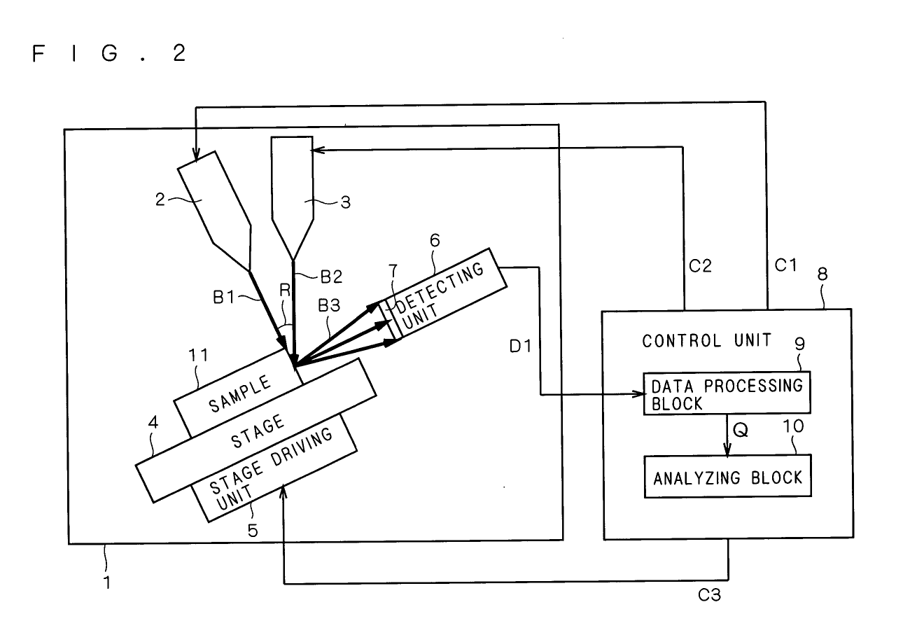

FIG. 2 is a block diagram showing the configuration of a crystal analyzing apparatus according to a modification of the first preferred embodiment. The optical axis of the electron beam emitting device 3 is perpendicular to the ground. The optical axis of the ion beam emitting device 2 is perpendicular to the top surfaces of the sample 11, stage 4, and stage driving unit 5 and is inclined at an angle R of approximately 20 to 30° with respect to the optical axis of the electron beam emitting device 3. In other respects the configuration is the same as that of FIG. 1.

Now, the operation of the crystal analyzing apparatus of the first preferred embodiment is described. FIG. 3 is a side view of the sample 11. First, the electron beam emitting device 3 emits an electron beam B2 to an arbitrary point (referred to as a pixel hereinafter) in the measured surface S1. Next, the detecting unit 6 detects an electron backscatter diffraction pattern B3 produced from that pixel as a result of the radiation of electron beam B2. The result of detection by the detecting unit 6 is inputted to the data processing block 9 as data D1. The data processing block 9 analyzes data D1 to obtain crystal orientation data P about that pixel. With the electron beam B2 scanning the measured surface S1, the detecting unit 6 detects an electron backscatter diffraction pattern from each pixel in the measured surface S1 and the data processing block 9 analyzes data D1, so as to sequentially obtain crystal orientation data about all pixels in the measured surface S1. As a result, two-dimensional distribution data K1 about the crystal orientation of the measured surface S1 is obtained. The two-dimensional distribution data K1 is stored in a memory not shown.

Next, the ion beam emitting device 2 emits an ion beam B1 to slice the sample 11, so as to form a section at a position inward from the measured surface S1 by a given distance L. The section thus formed is the next target surface S2. Then two-dimensional distribution data K2 about the crystal orientation of the measured surface S2 is obtained in the manner described above. Like the two-dimensional distribution data K1, the two-dimensional distribution data K2 is stored in the memory.

The operation steps above are repeated to sequentially obtain crystal-orientation two-dimensional distribution data K3, K4, . . . Kn about measured surfaces S3, S4, . . . Sn. Like the two-dimensional distribution data K1 and K2, the two-dimensional distribution data K3 to Kn are stored in the memory.

During the sequential formation of the plurality of sections of the sample 11, when the above-mentioned given distance L is on the order of micrometers (μm) or less, the path of the ion beam B1 is controlled by a scanning lens (not shown) provided in the ion beam emitting device 2, whereby the location illuminated by the ion beam B1 is controlled. On the other hand, when the given distance L is so large that the path cannot be controlled with the scanning lens, the control unit 8 controls the stage driving unit 5 to move the stage 4.

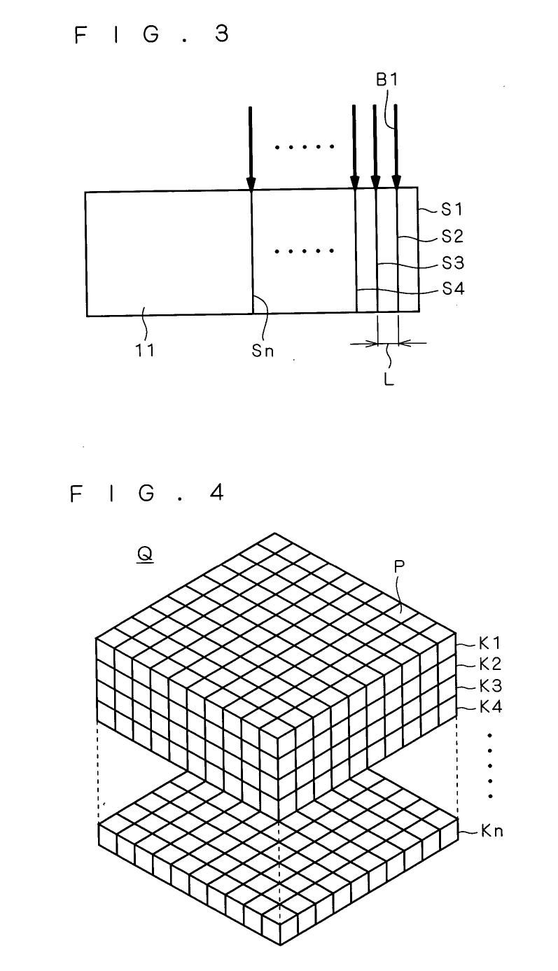

Next, the data processing block 9 stacks the two-dimensional distribution data K1 to Kn in the memory in this order to construct crystal-orientation three-dimensional distribution data Q. FIG. 4 is a schematic diagram showing an example of three-dimensional distribution data Q. The plurality of cuboids each represent crystal orientation data P about a pixel. A collection of multiple pieces of data P belonging to the same plane constitutes one of the two-dimensional distribution data K1 to Kn. The collection of two-dimensional distribution data K1 to Kn constitutes three-dimensional distribution data Q. The surface resolving power of data is determined by the dimensions of three sides (length, width, and height) of each cuboid that represents data P.

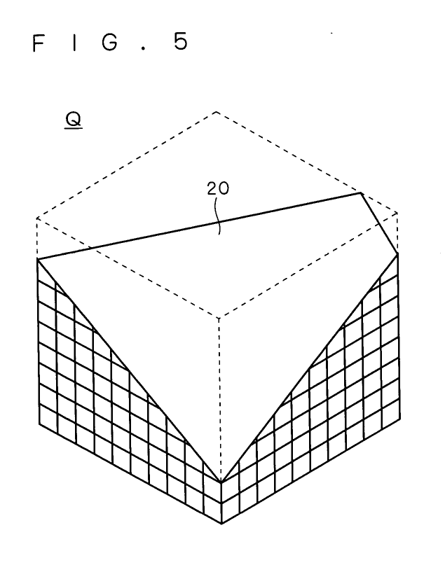

Referring to FIGS. 1 and 2, the three-dimensional distribution data Q about crystal orientation is inputted to the analyzing block 10. The analyzing block 10 defines an arbitrary section in the three-dimensional data Q. FIG. 5 is a schematic diagram showing an example of an arbitrary section defined in the three-dimensional data Q. A section 20 is defined as the arbitrary section. FIG. 6 is the plan view of the section 20. In the section 20, multiple pieces of data P about the crystal orientation of pixels are shown.

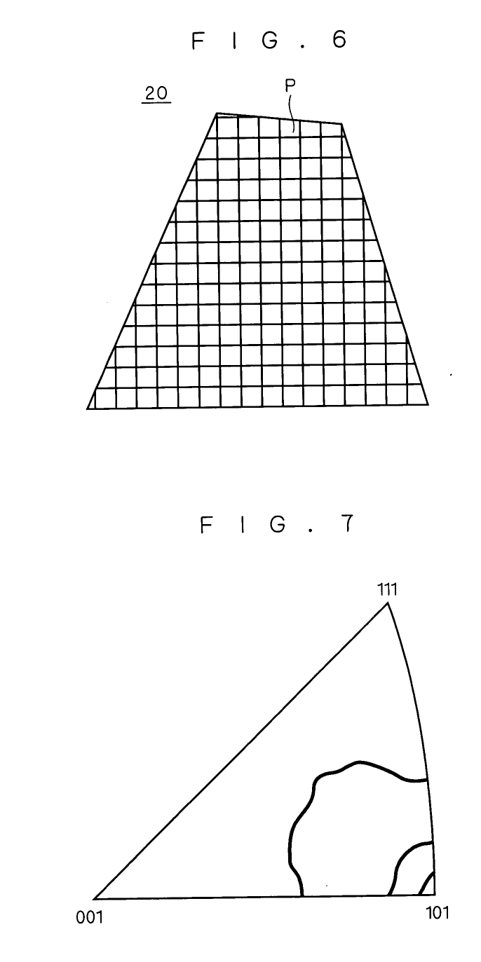

The analyzing block 10 conducts a crystal analysis about the section 20 using the multiple data P. In the first preferred embodiment, the analyzing block 10 carries out an analysis of preferred orientation using a pole figure or an inverse pole figure. FIG. 7 is a diagram showing an example of an inverse pole figure (an orientation distribution image) generated about the section 20.

Thus, according to the crystal analyzing apparatus of the first preferred embodiment, the data processing block 9 stacks two-dimensional distribution data K1 to Kn to construct crystal-orientation three-dimensional distribution data Q. The use of the three-dimensional distribution data Q thus enables three-dimensional crystal analysis. In addition, the analysis of preferred orientation can be performed about arbitrary sections defined in the three-dimensional data Q.

Second Preferred Embodiment

The first preferred embodiment has shown analyzing block 10 that performs the analysis of preferred orientation about the section 20. On the other hand, in a second preferred embodiment, analyzing block 10 performs analysis of grain size about the section 20.

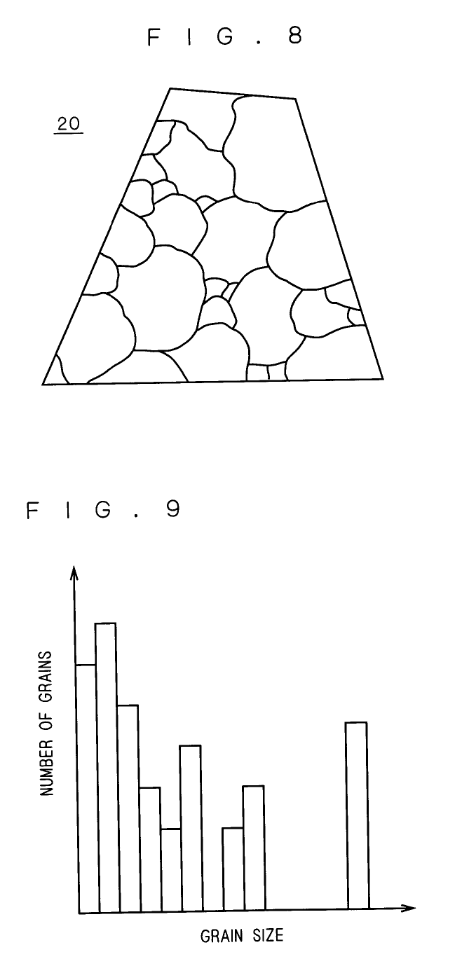

Analyzing block 10 recognizes grains in the section 20 shown in FIG. 6 on the basis of multiple data P appearing in the section 20 and generates a grain distribution image. FIG. 8 is a schematic diagram showing an example of a grain distribution image generated about the section 20.

Next, the analyzing block 10 approximates individual grains shown in FIG. 8 to circles and measures the diameter (μm) of each circle. Then, it performs a quantitative analysis of the grain size about the section 20 by, e.g. generating a graph (FIG. 9) showing the relation between the grain size and the number of grains.

The analyzing block 10 may perform a grain size analysis by obtaining the average area (μm²) of the circles obtained by approximation of the grains of FIG. 8, or by obtaining ASTM (American Society for Testing Materials) value. The ASTM value is an index that shows the number of grains per inch.

As described above, the crystal analyzing apparatus of the second preferred embodiment provides the effect that grain size analysis can be performed with respect to arbitrary sections defined in the three-dimensional data Q.

Third Preferred Embodiment

In the first preferred embodiment, analyzing block 10 performs the analysis of preferred orientation about the section 20. On the other hand, in a third preferred embodiment, analyzing block 10 performs analysis of grain boundary characteristics about the section 20.

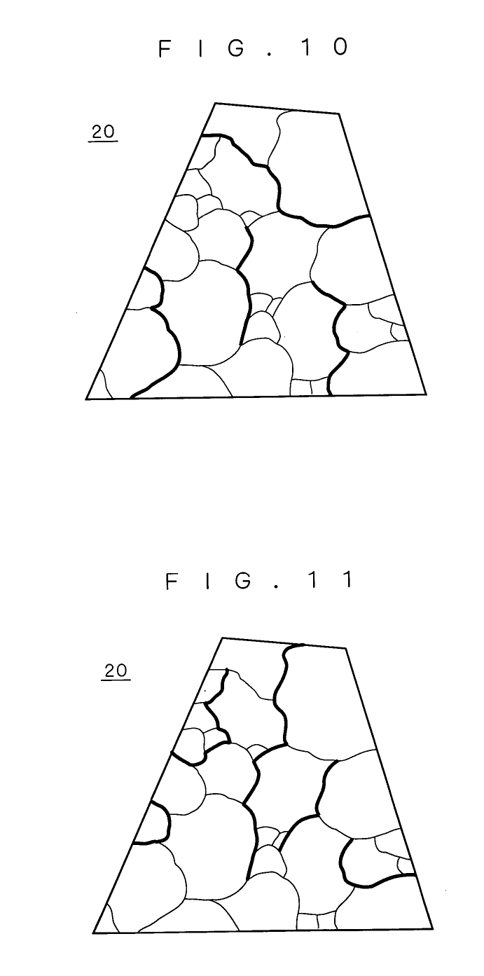

Analyzing block 10 recognizes the inclination of grain boundaries on the basis of multiple data P appearing in the section 20 shown in FIG. 6 to generate a grain boundary characteristic image. FIG. 10 is a schematic diagram showing an example of a grain boundary characteristic image generated about the section 20. The grain boundary characteristic image shows grain boundaries in different colors in accordance with the inclination.

As described above, the crystal analyzing apparatus of the third preferred embodiment provides the effect that analysis of grain boundary characteristics can be performed about arbitrary sections defined in three-dimensional data Q.

Fourth Preferred Embodiment

In the first preferred embodiment, analyzing block 10 performs the analysis of preferred orientation about the section 20. On the other hand, in a fourth preferred embodiment, analyzing block 10 performs analysis of Σ-value distribution about the section 20.

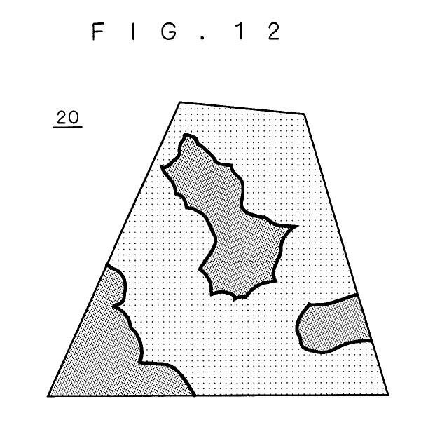

Analyzing block 10 recognizes Σ-values on the basis of multiple data P appearing in the section 20 shown in FIG. 6 to generate a Σ-value distribution image. The Σ-value indicates a ratio between the volume of a unit cell of the original crystal lattice and the volume of a unit cell of a coincidence lattice. FIG. 11 is a schematic diagram showing an example of a Σ-value distribution image generated with respect to the section 20. The Σ-value distribution image shows grain boundaries in different colors in accordance with the Σ-values.

As described above, the crystal analyzing apparatus of the fourth preferred embodiment provides the effect that Σ-value distribution analysis can be performed with respect to arbitrary sections defined in three-dimensional data Q.

Fifth Preferred Embodiment

In the first preferred embodiment, analyzing block 10 performs the analysis of preferred orientation about the section 20. However, in a fifth preferred embodiment, analyzing block 10 performs analysis of phase distribution about the section 20.

Analyzing block 10 recognizes phase distribution on the basis of multiple data P appearing in the section 20 shown in FIG. 6 to generate a phase distribution image. FIG. 12 is a schematic diagram showing an example of a phase distribution image generated about the section 20. The phase distribution image shows grains in different colors in accordance with differences of crystal system (i.e. phase difference).

As described above, the crystal analyzing apparatus of the fifth preferred embodiment provides the effect that phase distribution analysis can be performed about arbitrary sections defined in three-dimensional data Q.

Sixth Preferred Embodiment

In the first preferred embodiment, analyzing block 10 defines arbitrary section 20 in the three-dimensional data Q and performs a crystal analysis about the section 20. However, in a sixth preferred embodiment, analyzing block 10 extracts an arbitrary three-dimensional region from the three-dimensional data Q and performs a crystal analysis about that region.

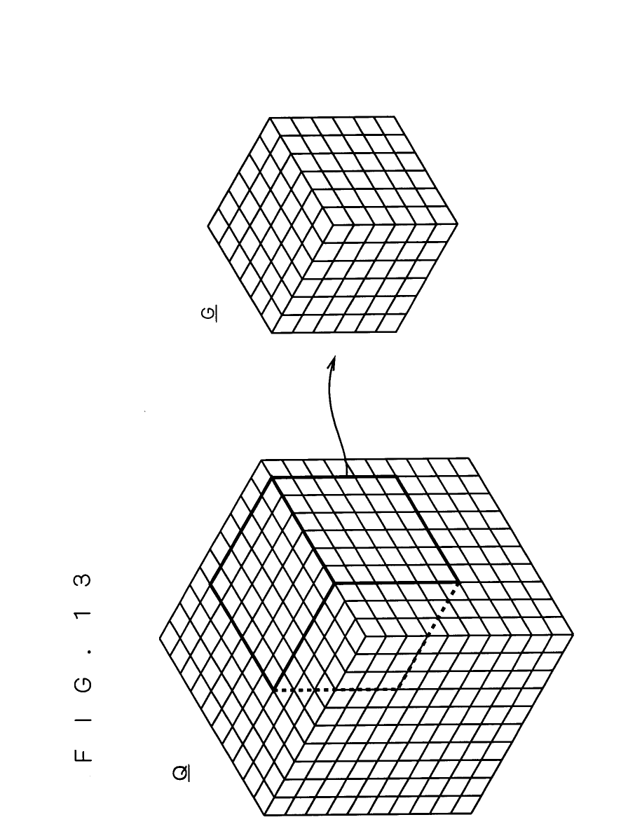

FIG. 13 is a schematic diagram showing an example of region G arbitrarily extracted from the three-dimensional data Q. The region G is formed of a plurality of pieces of data P about the crystal orientation of pixels.

Analyzing block 10 performs a crystal analysis about the region G using the multiple data P contained in the region G. In the sixth preferred embodiment, the analyzing block 10 performs an analysis of preferred orientation about the region G using a pole figure or an inverse pole figure.

Thus the crystal analyzing apparatus of the sixth preferred embodiment provides the effect that preferred orientation analysis can be performed about arbitrary three-dimensional regions extracted from three-dimensional data Q.

Seventh Preferred Embodiment

In the sixth preferred embodiment, analyzing block 10 performs preferred orientation analysis about the region G. However, in a seventh preferred embodiment, analyzing block 10 performs analysis of grain size about the region G.

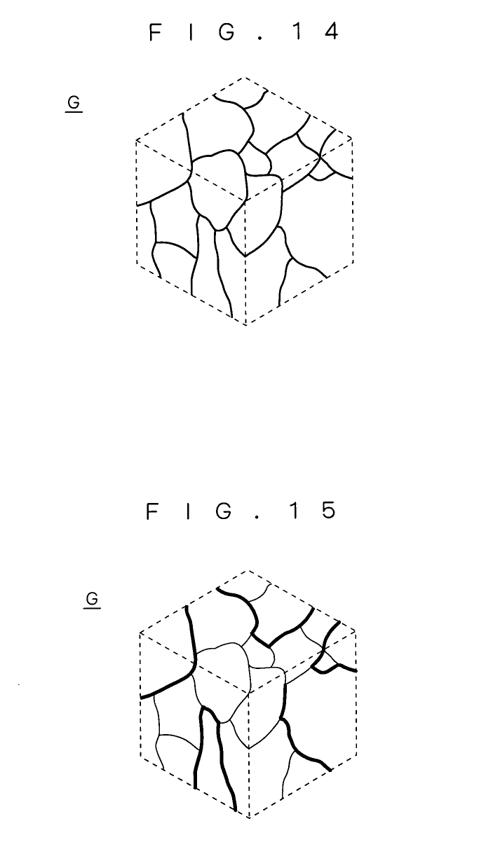

Analyzing block 10 recognizes grains in the region G on the basis of multiple data P contained in the region G shown in FIG. 13 to generate a grain distribution image. FIG. 14 is a schematic diagram showing an example of a grain distribution image generated about the region G.

Next, the analyzing block 10 approximates individual grains of FIG. 14 to spheres and measures the diameter (μm) of each sphere. Then it performs a quantitative analysis about the grain size with respect to the region G by, e.g. generating a graph showing the relation between the grain size and the number of grains (a graph like that shown in FIG. 9).

The analyzing block 10 may perform a grain size analysis by obtaining the mean volume (μm³) of spheres obtained by approximation of the grains of FIG. 14.

Thus, the crystal analyzing apparatus of the seventh preferred embodiment provides the effect that grain size analysis can be performed about arbitrary regions extracted from three-dimensional data Q.

Eighth Preferred Embodiment

In the sixth preferred embodiment, analyzing block 10 performs preferred orientation analysis about the region G. However, in an eighth preferred embodiment, analyzing block 10 performs analysis of grain boundary characteristics about the region G.

Analyzing block 10 recognizes the inclination of grain boundaries on the basis of multiple data P contained in the region G shown in FIG. 13 to generate a grain boundary characteristic image. FIG. 15 is a schematic diagram showing an example of a grain boundary characteristic image generated about the region G.

Thus, the crystal analyzing apparatus of the eighth preferred embodiment provides the effect that analysis of grain boundary characteristics can be performed with respect to arbitrary regions extracted from three-dimensional data Q.

Ninth Preferred Embodiment

In the sixth preferred embodiment, analyzing block 10 performs preferred orientation analysis about the region G. However, in a ninth preferred embodiment, analyzing block 10 performs analysis of Σ-value distribution about the region G.

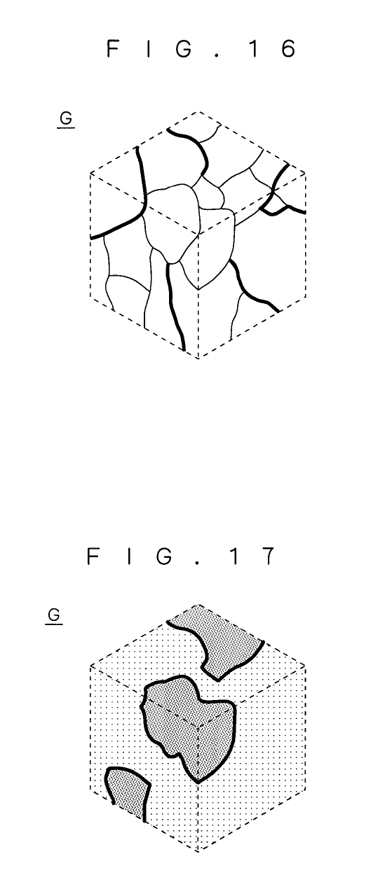

Analyzing block 10 recognizes Σ-values on the basis of multiple data P contained in the region G shown in FIG. 13 to generate a Σ-value distribution image. FIG. 16 is a schematic diagram showing an example of a Σ-value distribution image generated about the region G.

Thus, the crystal analyzing apparatus of the ninth preferred embodiment provides the effect that Σ-value distribution analysis can be performed about arbitrary regions extracted from three-dimensional data Q.

Tenth Preferred Embodiment

In the sixth preferred embodiment, analyzing block 10 performs the analysis of preferred orientation about the region G. However, in a tenth preferred embodiment, analyzing block 10 performs analysis of phase distribution about the region G.

Analyzing block 10 recognizes the phase distribution on the basis of multiple data P contained in the region G shown in FIG. 13 to generate a phase distribution image. FIG. 17 is a schematic diagram showing an example of a phase distribution image generated about the region G.

As described above, the crystal analyzing apparatus of the tenth preferred embodiment provides the effect that phase distribution analysis can be performed about arbitrary regions extracted from three-dimensional data Q.

While the invention has been described in detail, the foregoing description is in all aspects illustrative and not restrictive. It is understood that numerous other modifications and variations can be devised without departing from the scope of the invention.

What is claimed is:

1. A crystal analyzing apparatus comprising:
an ion beam emitting portion for emitting an ion beam onto a sample to sequentially form a plurality of sections of said sample;
an electron beam emitting portion for emitting an electron beam to each of said plurality of sections;
a detecting portion for detecting, with respect to each of said plurality of sections, an electron backscatter diffraction pattern produced from said sample as a result of the emission of said electron beam;
a data processing portion for constructing three-dimensional data about a crystal orientation distribution of said sample on the basis of results detected by said detecting portion; and
an analyzing portion for defining an arbitrary section in said three-dimensional data and performing a crystal analysis about said arbitrary section.

2. The crystal analyzing apparatus according to claim 1, wherein said crystal analysis is one of preferred orientation analysis, grain size analysis, grain boundary characteristic analysis, Σ-value distribution analysis, and phase distribution analysis.

3. A crystal analyzing apparatus comprising:
an ion beam emitting portion for emitting an ion beam onto a sample to sequentially form a plurality of sections of said sample;
an electron beam emitting portion for emitting an electron beam to each of said plurality of sections;
a detecting portion for detecting, with respect to each of said plurality of sections, an electron backscatter diffraction pattern produced from said sample as a result of the emission of said electron beam;
a data processing portion for constructing three-dimensional data about a crystal orientation distribution of said sample on the basis of results detected by said detecting portion; and
an analyzing portion for extracting an arbitrary three-dimensional region from said three-dimensional data and performing a crystal analysis about said arbitrary three-dimensional region.

4. The crystal analyzing apparatus according to claim 3, wherein said crystal analysis is one of preferred orientation analysis, grain size analysis, grain boundary characteristic analysis, Σ-value distribution analysis, and phase distribution analysis.
